(19) United States
(12) Patent Application Publication
(10) Pub. No.: US 2024/0321932 A1
(43) Pub. Date: Sep. 26, 2024

(54) THIN PHOTODETECTOR DEVICE AND FABRICATION THEREOF

(71) Applicant: ams-OSRAM AG, Premstätten (AT)

(72) Inventors: Rainer Minixhofer, Premstätten (AT); Jörg Siegert, Graz (AT); Angus Chan, Hsinchu City (TW); Franz Schrank, Graz (AT)

(21) Appl. No.: 18/575,774

(22) PCT Filed: Jun. 13, 2022
(86) PCT No.: PCT/EP2022/065970

§ 371 Date: Dec. 29, 2023

(30) Foreign Application Priority Data
Jul. 9, 2021 (DE) 10 2021 117 803.7

(51) Int. Cl. H01L 27/146

(52) U.S. Cl. CPC H01L 27/14689; H01L 27/14621; H01L 27/14636; H01L 27/14645; H01L 27/14685; H01L 27/14698

(57) ABSTRACT

In an embodiment a method for fabricating a photodetector device includes providing a carrier substrate, wherein a device layer is arranged at a main surface of the carrier substrate, and an insulating layer is arranged between the device layer and the carrier substrate, forming a plurality of photodetector elements in the device layer, forming an intermetal dielectric on the device layer, wherein contact pads electrically connected to the photodetector elements are embedded in the intermetal dielectric, forming pad openings in the intermetal dielectric, the pad openings reaching the contact pads so that the contact pads are accessible via the pad openings, mounting a handling substrate on the intermetal dielectric, removing the carrier substrate, singulating the plurality of photodetector elements such that a plurality of separate photodetector chips comprising one photodetector element are formed and releasing the photodetector chips from the handling substrate.

### CROSS-REFERENCE TO RELATED APPLICATIONS

This patent application is a national phase filing under section 371 of PCT/EP2022/065970, filed Jun. 13, 2022, which claims the priority of German patent application 102021117803.7, filed Jul. 9, 2021, each of which is incorporated herein by reference in its entirety.

### TECHNICAL FIELD

The present disclosure relates to a photodetector device and a method for fabricating such a photodetector device.

### BACKGROUND

Due to the requirement of a very low height of backside-illuminated photodetector chips to be integrated on a backplane of a display with sensing functions one needs to establish a process how to generate such thin photodetector chips and prepare them for the transfer process. Above a certain height of the photodetector chips the topography would be too large for subsequent process steps like the integration of light emitting devices, such as μLEDs. Currently, classical methods for preparing such thin photodetector chips, such as backend assembly by wafer grinding or etch based thinning, lack the required accuracy.

### SUMMARY

Embodiments provide a method for fabricating a thin photodetector device. Further embodiments provide a photodetector device and a display comprising the photodetector device.

The disclosure aims to establish a process integration flow to generate thin, e.g. smaller than 10 μm, photodetector chips for transfer to a target substrate as the backplane of a display. With such a heterogeneous integration usually incompatible materials like III-V semiconductors and silicon could be combined together to enable novel sensor products or even bi-directional (sensing/emitting) displays. Moreover, the generation of these photodetector chips may be covered by a frontend process flow.

In an embodiment the method for fabricating a photodetector device comprises providing a carrier substrate, wherein a device layer is arranged at a main surface of the carrier substrate, and an insulating layer is arranged between the device layer and the carrier substrate.

The carrier substrate may comprise a semiconductor material, for example silicon (Si). The carrier substrate has a main plane of extension. The main plane of extension extends in lateral directions. In a transversal direction, which runs perpendicular to the lateral directions, the insulating layer is arranged on the main surface of the carrier substrate. The insulating layer may comprise silicon dioxide (SiO₂), by way of example. In the transversal direction, the device layer is arranged on or above the insulating layer. This can mean that the device layer is arranged on a side of the insulating layer facing away from the carrier substrate. The device layer may comprise a semiconductor material, for example Si. The device layer may be doped for first type of electric conductivity, for example n-type. However, the first type of electric conductivity may also be p-type. This may mean that the device layer may have impurities occupied by spurious atoms, for example phosphor (P), arsenic (As), boron (B) or the like. In the transversal direction, the device layer may have a thickness of at least 3 μm and at most 20 μm. Alternatively, the device layer may have a thickness of at least 5 μm and at most 10 μm. The device layer may have a specific electrical resistivity of about 100002 cm.

The carrier substrate, the insulating layer and the device layer may form a so-called SOI wafer (SOI: Silicon On Insulator). The interface of the insulating layer to the device layer defines the final thickness of the resulting photodetector device. The carrier substrate ensures the mechanical stability for the layer stack during frontend processing. The carrier substrate is removed in a later process step, wherein the insulating layer is used as an etch stop layer. Thus, the remaining layers, in particular the device layer, can be very thin. Thus, the photodetector device is suitable for backside illumination (BSI) and can be integrated in thin electronic devices such as displays.

The method further comprises forming a plurality of photodetector elements in the device layer. Forming the photodetector elements may comprise forming pn-junctions in the device layer. Each photodetector element may be formed by at least one photodiode. Each photodetector element may also comprise more than one photodiode, for example an array of photodiodes. Forming pn-junctions can by conducted by one or more ion implantation steps. By implantation the device layer is counterdoped at least in places. Thus, after forming pn-junctions, regions of the device layer are doped for a second type of electric conductivity, for example p-type.

In particular, the photodetector elements may be formed by PIN photodiodes, where an intrinsically doped region (I-region) is arranged between a P+-type doped anode region and an N+-type doped cathode region. The P+-type doped anode region and the N+-type doped cathode region are thus not in direct contact. When a reverse voltage is applied, a larger space charge region is formed than in a classical pn-diode. When electromagnetic radiation impinges the photodetector device, photo-induced charge carriers are generated in the space charge region, which leads to a photocurrent. By measuring the photocurrent, electromagnetic radiation can be detected.

In an embodiment, only photodetector elements are formed in the device layer. This can mean that no further circuits, in particular readout circuits, are formed in the device layer. Electrical signals can be read out by an external readout device. Thus, the photodetector elements can be compact and may have small dimensions in both lateral and transversal directions.

The method further comprises forming an intermetal dielectric on the device layer, wherein contact pads electrically connected to the photodetector elements are embedded in the intermetal dielectric.

The intermetal dielectric comprises an electrically isolating material, for example SiO₂. In the transversal direction, the intermetal dielectric is arranged on the device layer on a side facing away from the insulating layer. One or more wiring layers are arranged in the intermetal dielectric, wherein the contact pads are formed by one of the wiring layers. The contact pads are electrically connected to terminals of the photodetector elements, in particular to the anode and cathode terminal of the photodiodes. The wiring layers and in particular the contact pads, may comprise a metal, for example aluminum (Al) and/or tungsten (W).

The method further comprises forming pad openings in the intermetal dielectric. The pad openings reach the contact pads. The pad openings reach from a side of the intermetal dielectric that faces away from the device layer towards the contact pads. Forming the pad openings may comprise an etching process that removes portions of the intermetal dielectric. The pad openings may extend in the transversal direction. The contact pads are accessible via the pad openings.

The method further comprises mounting a handling substrate on the intermetal dielectric. The handling substrate is mounted on the intermetal dielectric such that is covers the pad openings. For example, the handling substrate is another semiconductor wafer that is bonded on the intermetal dielectric. In particular, a permanent bonding technique can be applied. In an embodiment, the handling substrate is bonded on the intermetal dielectric by means of an adhesive. In other embodiments, a fusion bonding technique is used. In further embodiments, the handling substrate can be an electrostatic wafer or chuck that is mounted on the intermetal dielectric by applying an electrostatic force. It is even possible to mount the handling substrate on the intermetal dielectric by a surface roughening method. By applying the handling substrate the layer stack can be flipped for backside treatment.

The method further comprises removing the carrier substrate. The removal of the carrier substrate can be conducted during backside treatment. Removing the carrier substrate can comprise grinding and/or etching. For example, in a first step a main portion of the carrier substrate is removed by chemical mechanical polishing (CMP). In a second step, an etching step is applied to the remaining carrier substrate, wherein the insulating layer functions as etch stop layer. This means that removing the carrier substrate exposes the insulating layer. By this procedure the insulating layer may be thinned. For example, the thinned insulating layer may have a thickness of at least 700 nm. By removing the carrier substrate the resulting layer stack can be thin, such that the photodetector device can be integrated in thin electronic devices, for example displays. Moreover, the photodetector elements are close to a radiation entrance side, and electromagnetic radiation does not need to travel through the carrier substrate.

The method further comprises singulating the plurality of photodetector elements, such that a plurality of separate photodetector chips comprising one photodetector element are formed.

Singulating may comprise an etching process. In this case, etching lanes may be formed from the exposed insulating layer to the handling substrate. Etching can be conducted in a frontend fab (e.g. a CMOS frontend fab). Advantageously, most of the fabrication of the photodetector device can be conducted in one and the same fabrication plant. Moreover, by an etching process precise and narrow lanes can be provided. Compared to classical dicing nearly no debris occurs.

However, in another embodiment, the photodetector elements are singulated by a laser ablation method. Laser ablation dicing can be conducted in a fabrication plant different than a frontend fabrication plant. Advantageously, further materials may be used that would lead to contamination problems in a frontend fab. For example, an optional interference filter, that comprises silver (Ag) or the like, can be applied above each photodetector element before singulating.

After singulating, a plurality of photodetector chips are attached to the handling substrate, but separated from each other. Each photodetector chip may comprise one photodetector element only, including the intermetal dielectric above the photodetector element with respective contact pads. Advantageously, each photodetector chip has small dimensions in the lateral directions as well as in the transversal direction. In an embodiment, each photodetector chip has a height in the transversal direction, the height being at most 10 μm, at most 15 μm or at most 20 μm. In an embodiment, each photodetector chip has a width in lateral directions, the width being at most 20 μm, at most 25 μm or at most 30 μm.

The method further comprises releasing the photodetector chips from the handling substrate. Releasing the photodetector chips from the temporary handling substrate may be performed by either underetch them, or by releasing the electrostatic force of the handling substrate, depending on the bonding method described above. In a preferred embodiment, releasing comprises an underetch, wherein a portion of the intermetal dielectric near the interface to the handling substrate is removed. An etch stop layer may prevent further etching of the intermetal dielectric. The release process allows all detector chips to be released from the handling substrate at once.

The method further comprises transferring the photodetector chips onto a target substrate. The target substrate comprises a main surface. The photodetector chips are arranged on the target substrate such that the intermetal dielectric faces the main surface of the target substrate.

The target substrate has a main plane of extension that runs in lateral directions. The target substrate may be a printed circuit board (PCB) or a glass substrate, by way of example. In another embodiment, the target substrate is a backplane of a display. A multitude of photodetector chips may be transferred in parallel. For example, an elastomer stamp is used for transferring the photodetector chips. However, conventional pick-and-place devices may also be used for transferring the photodetector chips.

By transferring the photodetector chips, a multitude of photodetector chips may be arranged on the target substrate. The photodetector chips may be attached to the target substrate, for example by means of an adhesive and/or by thermo-compression bonding. The contact pads of each photodetector chip may be electrically connected to electrodes on the target substrate. The photodetector chips may be arranged on the target substrate at predetermined places. For example, the photodetector chips are arranged on the target substrate in a grid-like fashion. There may be a distance between each of the photodetector chips. Moreover, other (opto-)electronic devices may be arranged on the target substrate. For example, light emitting elements may be arranged on the main surface of the target substrate at places between the photodetector chips.

The photodetector device is formed by the target substrate and the photodetector chips that are arranged on the target substrate. Electromagnetic radiation enters the photodetector chips on a side facing away from the target substrate. This means that electromagnetic radiation enters the photodetector chips from a backside of the photodetector chips. Thus, the photodetector chips are backside illuminated (BSI). As a multitude of photodetector chips are arranged on the target substrate, an optical resolution is provided. Thus, the photodetector device may be used for camera applications. The photodetector device may be thin since the photodetector chips on the target substrate are thin. Thus, the photodetector device can be used in thin electronic devices, for example in spectral sensing displays or other smart devices.

In an embodiment of the method, the method further comprises providing a highly doped buried layer between the insulating layer and the device layer. The highly doped buried layer comprises the same type of electric conductivity as the device layer.

The buried layer is arranged on a side of the insulating layer facing away from the carrier substrate. The buried layer may comprise a semiconductor material, for example Si. The buried layer may be epitaxially grown. The buried layer may also be formed by implantation. If the device layer is doped for the first type of electric conductivity, the buried layer is doped for the first type of electric conductivity a well. This can mean that the buried layer has an n-type doping. Thus, the buried layer may form an N+-type buried layer. The buried layer completely covers the insulating layer. In the transversal direction the buried layer has a thickness, which may be tuned to the required response of the photodetector device in the blue range of wavelengths. For example, the thickness of the buried layer is smaller than 1 μm.

As the photodetector chips are backside illuminated, the entrance side of the photodetector elements for electromagnetic radiation is the side where the buried layer is arranged. The penetration depth of the electromagnetic radiation depends on its wavelength. Light of short wavelengths, in particular light in the blue wavelength range, penetrates the device layer only a few nanometers. The charge carriers generated there, but also charge carrier diffusing towards the surface of the substrate, can easily recombine and thus do not contribute to the photocurrent. However, by applying the highly doped buried layer, recombination of charge carriers is prevented. Minority charge carriers are repelled away from the buried layer due to the higher doping concentration of the buried layer in comparison to the doping concentration of the device layer. Due to the higher doping the Fermi level is closer to the edge of the valence band, which increases the energy barrier for the minority charge carriers diffusing towards the buried layer. Therefore, the photo-induced charge carriers are prevented from recombining at the main surface and can contribute to the photocurrent. The spectral responsivity of the photodetector device is therefore enhanced.

In an embodiment of the method, the method further comprises forming trenches penetrating the device layer. Forming the trenches is preferably conducted before forming the intermetal dielectric on the device layer. The trenches each surround one of the detector elements. The trenches are filled with a filling material.

Forming the trenches may comprise an etching step for removing a portion of the device layer. Each trench completely penetrates the device layer and reaches the insulating layer. Each photodetector element is surrounded by the trenches in lateral directions. This can mean that the photodetector elements are separated from each other by the trenches. The trenches are completely filled with the filling material. The filling material may comprise an electrically isolating material, for example SiO₂. However, other materials are also possible. The trenches provide a clear definition of the lines where the detector elements need to be singulated. Thus, forming trenches facilitates the later singulating step and makes it more accurate.

In an embodiment, forming the intermetal dielectric on the device layer further comprises forming a passivation layer above the contact pads. The intermetal dielectric may be deposited in one or more deposition steps, wherein the passivation layer may be formed between one of these deposition steps. In particular, the passivation layer is formed after forming the contact pads within the intermetal dielectric. Thus, in the transversal direction, the passivation layer is arranged above the contact pads. There may be a distance in the transversal direction between the passivation layer and the contact pads. The passivation layer may comprise silicon nitride (Si₃N₄), by way of example. In particular, the passivation layer may comprise a material that is robust against an etchant of the later releasing process. In particular, the passivation layer is robust against hydrogen fluoride (HF). Thus, the passivation layer can function as an etch stop layer in the later releasing process in order to prevent further etching of the intermetal dielectric. Moreover, the passivation layer prevents other physical damage of the photodetector chips, e.g. scratches or the like.

In another embodiment, forming the intermetal dielectric on the device layer comprises forming a passivation layer on the contact pads. This can mean that the passivation layer is direct contact with the contact pads. The pad openings are formed through the passivation layer. This can further improve the later releasing process since sidewalls of the pad openings are protected against the etchant by means of the passivation layer. This improves the reliability of the photodetector device.

In an embodiment of the method, the method further comprises filling the pad openings with an electrically conductive plug. Filling the pad openings with an electrically conductive plug is conducted after forming the pad openings and before mounting a handling substrate onto the intermetal dielectric.

The electrically conductive plug may completely fill the pads openings. The electrically conductive plug may comprise, for example, an aluminum-germanium alloy (AlGe), indium tin oxide (ITO), titanium tungsten (TiW) or tungsten (W). The electrically conductive plug may in particular be robust against the etchant of the later releasing process. In particular, the electrically conductive plug is robust against HF. Thus, the electrically conductive plug can function as an etch stop layer in the later releasing process in order to prevent further etching of the intermetal dielectric at the sidewalls of the pad openings. Furthermore the electrically conductive plug may already be usable for a later thermo-compression bonding, such that the contact pads can be electrically connected to electrodes on the target substrate.

Additionally or alternatively to filling the pad openings with an electrically conductive plug, sidewalls of the pad openings are covered by a spacer. A spacer layer may be deposited into the pad openings and etched back, such that the spacer remains on the sidewalls of the pad openings. The spacer may comprise the same material as the passivation layer, i.e. Si₃N₄. Thus, the spacer is robust against the etchant of the later releasing process. In particular, the spacer is robust against HF. Thus, the spacer can function as an etch stop layer in the later releasing process in order to prevent further etching of the intermetal dielectric at the sidewalls of the pad openings.

In an embodiment of the method, the method further comprises, after removing the carrier substrate, forming an interference filter on the insulating layer. Removing the carrier substrate exposes the insulating layer. Thus, the interference filter can be arranged on a side of the insulating layer that faces away from the device layer. The interference filter may be bandpass filter or a cut-off filter. By means of the interference filter, undesired wavelengths can be chopped away from the wavelength range to be detected. The interference filter can be formed by a layer stack. The layer stack may comprise layers of different materials. The interference filter may comprise dielectrics. However, the interference filter may also comprise silver (Ag), hafnium (Hf) and/or niobium (Nb), by way of example.

The interference filter may cover the entire insulating layer. This can mean that the interference filter is not structured. Thus, the interference filter may be diced (e.g. ablation dicing) together with the remaining photodetector chips. Advantageously, the integration of the interference filter is done before singulating of the photodetector elements. This results in an efficient filter integration without the need to structure the interference filter, because it is structured together with the device layer.

In another embodiment, the interference filter is structured. This can mean that the layer stack comprised by the interference filter is structured by a photolithographic process, for example by a lift-off procedure or by a plasma etch step. By means of structuring the interference filter, the layer stack comprised by the interference filter may only be arranged in places, in particular above a respective photodetector element. The interference filter forms a radiation entrance side of each photodetector chip. In case that no interference filter is arranged at the insulating layer, the insulating layer forms the radiation entrance side of the respective photodetector chip.

In an embodiment of the method, the method further comprises applying a polymer encapsulation that covers side surfaces of the photodetector chips. Applying the polymer encapsulation is conducted after singulating the plurality of photodetector elements.

The polymer encapsulation may comprise a dark polymer. This can mean that the polymer encapsulation is opaque for electromagnetic radiation to be detected. In a first step, the polymer may deposited such that it covers the radiation entrance side as well as the side surfaces of the photodetector chips. This means that the polymer completely encapsulates the photodetector chip. In a second step the polymer is removed from the radiation entrance side, such that the radiation entrance is exposed again. The polymer encapsulation may be provided to reduce particle generation during the transfer process and to protect the top surface of the detector chips, i.e. the radiation entrance side, during subsequent handling. Moreover, since the polymer may opaque for electromagnetic radiation to be detected, the polymer encapsulation shields the photodetector chip from stray light that would enter the photodetector chip at its side surfaces. Thus, the polymer encapsulation provides an aperture of the photodetector chip. Thus, electromagnetic radiation can enter the photodetector chip only at the radiation entrance side, where no polymer encapsulation is present.

In an embodiment of the method, releasing the photodetector chips from the handling substrate comprises an underetch. During the underetch parts of the intermetal dielectric are removed. An etch stop layer is configured to prevent further etching of the intermetal dielectric. The underetch process may comprise applying an etchant, which may be HF vapor, for example. The etchant reaches the intermetal dielectric at the interface to the handling substrate.

In case that a polymer encapsulation is present at the side surfaces of each photodetector chip, the polymer encapsulation may have weak spots at the interface to the handling substrate or may be porous, such that the etchant can penetrate through the polymer encapsulation. In turn, the intermetal dielectric is etched by the etchant releasing the photodetector chips from the handling substrate. The photodetector chips may still weakly fixed to the handling substrate by means of the polymer encapsulation and/or by means of the electrically conductive plugs or spacers in the pad openings.

The etch stop layer is configured to be resistant to the etchant. Thus, the etch stop layer protects against further etching. The etch stop layer is provided to ensure that the etchant, e.g. the HF vapor, only etches the intermetal dielectric near the interface to the handling substrate. In one embodiment, the passivation layer serves as etch stop layer. The electrically conductive plug and/or the spacers may serve as etch stop layer as well.

Releasing the photodetector chips from the handling substrate by means of an underetch has the advantage of a massively parallel procedure, such that all photodetector chips are released at once. Moreover, no mechanical force is necessary. The releasing process is therefore clean and accurate.

In another embodiment, releasing the photodetector chips from the handling substrate comprises releasing an electrostatic force applied on the handling substrate. In even another embodiment, releasing the photodetector chips from the handling substrate comprises applying a shear force to the photodetector chips and/or to the handling substrate.

In an embodiment of the method, transferring the photodetector chips onto the target substrate comprises a parallel transfer of a multitude of photodetector chips. This means that the multitude of photodetector chips can be transferred at once. This in turn saves production time and costs.

In an embodiment, this parallel transfer is conducted by using an elastomer stamp. The elastomer stamp may comprise a low-pressure injection molded silicone rubber, wherein lithographically defined posts are configured for a selective transfer of the photodetector chips. A multitude of such posts can be arranged on the elastomer stamp. Thus, it is possible that a multitude of photodetector chips are transferred in parallel. The photodetector chips may have small dimensions due to the transfer through an elastomer stamp. Specifically, the dimensions may be smaller than when the photodetector chips are picked up by other transfer devices, like pick-and-place devices. Moreover, alignment of the photodetector chips on the target substrate may be redundant, as the final position of the photodetector chips on the target substrate is already defined by the posts of the elastomer stamp. However, conventional placement devices other than an elastomer stamp may also be used to transfer the photodetector chips onto the target substrate.

In an embodiment, the method further comprises electrically connecting the contact pads to electrodes that are arranged on the main surface of the target substrate. For example, this can be achieved by thermo-compression bonding. The electrodes can comprise a metallic material, for example gold (Au). For example, the electrodes form micro-bumps that are aligned to the pad openings, such that the electrodes reach into the pads openings. This means that the land pattern formed by the electrodes on the target substrate matches the arrangement of pad openings of the photodetector chip. In embodiments, where the pad openings are filled by an electrically conductive plug, the electrically conductive plug can be used for the thermo-compression bonding as well. Advantageously, no wire bonding is necessary, such that the footprint of each photodetector chip can be kept small.

Furthermore, a photodetector device is provided that can be produced by the above fabrication method. The photodetector device is provided for detection of electromagnetic radiation, for example for radiation in the visible wavelength range. All features disclosed for the method are also disclosed for the photodetector device and vice-versa.

In an embodiment, the photodetector device comprises a target substrate. The target substrate comprises a main surface. Electrodes may be arranged on the main surface of the target substrate.

The photodetector device further comprises a multitude of photodetector chips. Each photodetector chip comprises a device layer that is arranged at the backside of the photodetector chip. Further, a photodetector element is arranged in the device layer. Each photodetector chip further comprises an intermetal dielectric that is arranged at the front side of the photodetector chip. Contact pads are embedded in the intermetal dielectric. Further, the contact pads are electrically connected to the photodetector elements. The contact pads are accessible via pad openings in the intermetal dielectric.

In the photodetector device each detector chip is mounted on the target substrate. The detector chips are arranged on the target substrate such that the front side of each detector chip faces the main surface of the target substrate. Further, the contact pads are electrically connected to the electrodes.

Each photodetector chip of the photodetector device is backside illuminated. This means that electromagnetic radiation enters the photodetector chips on a side facing away from the target substrate. A radiation entrance side of the photodetector chip may be formed by an insulating layer and/or an interference filter that is arranged on the device layer. Advantageously, the electrical interconnections from the electrodes on the target substrate via the contact pads to the photodetector elements can be short and no wire bonding is necessary. Moreover, the photodetector element, which may be a photodiode for instance, is close to the radiation entrance side of the photodetector chip. Thus, the photodetector chips can be thin, such that the photodetector device can be integrated in thin electronic devices such as displays.

In an embodiment, each photodetector chip further comprises a highly doped buried layer arranged on the device layer at a side facing away from the intermetal dielectric. The highly doped buried layer has the same type of electric conductivity as the device layer.

The property of being buried refers to the fabrication process, where the device layer is arranged on top of the buried layer, as mentioned above. In the resulting photodetector chips the buried layer is however above the device layer, since the layer stack is flipped. The buried layer is arranged between the device layer and the radiation entrance side. The buried layer may comprise a semiconductor material, for example Si. The buried layer may be epitaxially grown. The buried layer may also be formed by ion implantation. If the device layer is doped for the first type of electric conductivity, the buried layer is doped for the first type of electric conductivity a well. This can mean that the buried layer has an n-type doping. Thus, the buried layer may form an N+-type buried layer. In the transversal direction the buried layer has a thickness, which may be tuned to the required response of the photodetector device in the blue range of wavelengths. For example, the thickness of the buried layer is smaller than 1 μm. Due to the buried layer photo-induced charge carriers are prevented from recombining at the main surface and can contribute to the photocurrent. The spectral responsivity of the photodetector device is therefore enhanced.

In an embodiment, the photodetector element forms a photodiode comprising at least one pn-junction and a space charge region.

The device layer has a base doping for the first type of electric conductivity, for example n-type. Region in the device layer are counterdoped, such that they form regions of a second type of electric conductivity, for example p-type. Other regions of the device layer may additionally doped for the first type of electric conductivity to increase the doping concentration. In particular, an n+-type cathode region and a p+-type anode region is formed in the device layer. The anode region and the cathode region may be in direct contact to each other or may be separated by an intrinsic region. In case of an intrinsic region, a PIN photodiode is formed in the device layer. When a reverse voltage is applied, a larger space charge region is formed than in the classic pn-photodiode. Since the intrinsic region contains only a few free charge carriers, it is highly resistive. By means of the photodiode electromagnetic radiation can be detected, as photo-induced charge carrier are generated in the space charge region leading to a photocurrent.

Additionally, the photodetector element may comprise further pn-junctions. For example, a guard ring could be arranged in the periphery of the photodetector element, wherein the guard ring comprises n+-type and p+-type zones. Due to the guard ring leakage can be reduced.

In an embodiment, the space charge region of the photodetector element has a distance to the radiation entrance side of the photodetector chip. The distance is such that incident electromagnetic radiation in the visible range generates photo-induced charge carriers in the space charge region. Due to the backside illuminated arrangement, the space charge region is close to the radiation entrance side of each photodetector chip. Thus, the number of photo-induced charge carriers can be increased and the responsivity of the photodetector device can be enhanced. Moreover, the distance between the space charge region and the radiation entrance side can be small, such that a thin device is realized.

In an embodiment, each photodetector chip further comprises an interference filter arranged on or above the device layer at the backside of the photodetector chip facing incident electromagnetic radiation. In this case, the interference filter forms the radiation entrance side. The interference filter may be bandpass filter or a cut-off filter. By means of the interference filter, undesired wavelengths can be chopped away from the wavelength range to be detected. The interference filter can be formed by a layer stack. The layer stack may comprise layers of different materials. The interference filter may comprise dielectrics. However, the interference filter may also comprise silver (Ag), hafnium (Hf) and/or niobium (Nb), by way of example.

In an embodiment, each photodetector chip further comprises a polymer encapsulation that covers side surfaces of the photodetector chip. The polymer encapsulation may comprise a dark polymer. This can mean that the polymer encapsulation is opaque for electromagnetic radiation to be detected. The polymer encapsulation protects the photodetector chip from physical damage. Moreover, the polymer encapsulation shields the photodetector chip from stray light that would enter the photodetector chip at its side surfaces. Thus, the polymer encapsulation may be configured to provide an aperture of the photodetector chip.

In an embodiment, in the intermetal dielectric of the photodetector chips at most one wiring layer is arranged. In another embodiment, at most two wiring layers are arranged in the intermetal dielectric. The contact pads are formed by the at most one wiring layer, or, respectively, by one of the at most two wiring layers.

In the photodetector chips only one photodetector element can be arranged. This can in particular mean that no further (opto-)electronic components are arranged in the photodetector chips, which would have to be electrically connected. Thus, the wiring can be kept simple and one or two wiring layer(s) may be sufficient. Thus, the electrical interconnection from the photodetector element via the contact pads to the electrodes on the target substrate can be short, which decreases serial resistances and/or inductances. This in turn leads inter alia to short response times.

In an embodiment, each photodetector chip has a height in the transversal direction. In an embodiment, the height is at most 10 μm. In another embodiment, the height is at most 15 μm. In even another embodiment, the height is at most 20 μm. Due to the small height the topography of the photodetector device is reduced. This facilitates the integration of further (opto-)electronic devices on the target substrate. For example, light emitting elements like micro light emitting diodes (μLEDs) can be arranged on the target substrate. Above a certain height the topography would get too large for subsequent process steps like μLED top electrode integration.

In an embodiment, each photodetector chip has a width in lateral directions. In an embodiment, the width is at most 20 μm. In another embodiment, the width is at most 25 μm. In even another embodiment, the width is at most 30 μm. Each photodetector chip may comprise only one photodetector element, such that a small lateral dimension can be maintained. Due to the small width an optical resolution sufficient for camera applications can be achieved. This can mean that the multitude of photodetector chips may be arranged in a grid-like fashion, such that an array of photodetector chips is formed.

In an embodiment, the target substrate forms a backplane of a display. This can mean that light emitting elements are arranged between the photodetector chips on the target substrate. For example, the light emitting elements can be μLEDs. For example, the light emitting elements emit light in the red, green and blue wavelength range. In one embodiment, the direction of light emission of the light emitting elements matches the field of view (FoV) of the photodetector chips.

Further embodiments of the photodetector device become apparent to the skilled reader from the embodiments of the fabrication method described above.

Furthermore, a display is provided that comprises the photodetector device. This means that all features disclosed for the photodetector device are also disclosed for and applicable to the display and vice-versa.

The display may form a wearable device display. Alternatively, the display forms a television display. Alternatively, a computer display, a laptop display or a tablet display is provided. In an embodiment, the display forms a smartphone display. In even another embodiment, the display is an automotive head-up display. Advantageously, the display is a bi-directional display with a light sensing and light emitting function. Thus, the display can be integrated in smart devices.

### BRIEF DESCRIPTION OF THE DRAWINGS

The following description of Figures may further illustrate and explain aspects of the photodetector device and the fabrication method thereof. Components and parts of the sensor arrangement that are functionally identical or have an identical effect are denoted by identical reference symbols. Identical or effectively identical components and parts might be described only with respect to the Figures where they occur first. Their description is not necessarily repeated in successive Figures.

FIGS. 1-11 show intermediate steps of fabricating a photodetector device;

FIG. 12 shows an exemplary embodiment of a photodetector device; and

FIG. 13 shows a display comprising a photodetector device.

### DETAILED DESCRIPTION OF ILLUSTRATIVE EMBODIMENTS

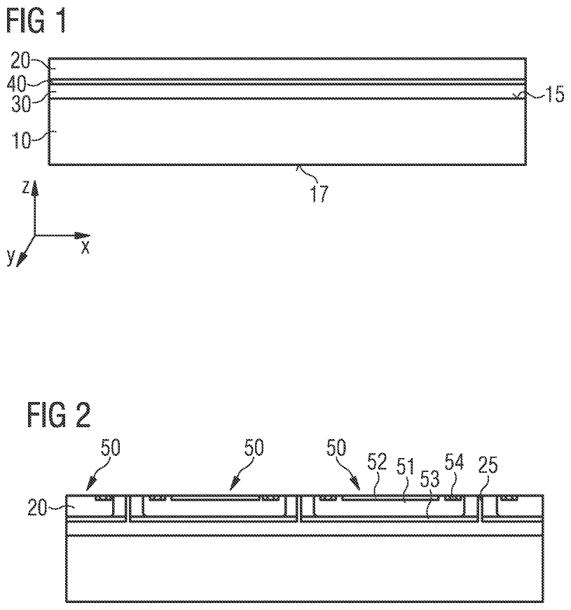

In FIGS. 1 to 11 intermediate steps of fabricating a photodetector device are shown. Different embodiments of the photodetector device derive from alternative options in the fabrication process.

The fabrication process may start according to FIG. 1 with providing a carrier substrate 10. The carrier substrate 10 has a main plane of extension. The main plane of extension extends in lateral directions x, y. The carrier substrate 10 may comprise a semiconductor material, for example silicon (Si). The carrier substrate 10 comprises a main surface 15 and a rear surface 17 opposite to the main surface.

An insulating layer 30 is arranged on the carrier substrate 10 at its main surface 15. This means that in a transversal direction z the insulating layer 30 is arranged above the carrier substrate 10. The insulating layer comprises an electrically isolating material, for example silicon oxide (SiO₂). In lateral directions x, y the insulating layer 30 runs parallel to the carrier substrate 10. In the transversal direction the insulating layer has a thickness. For example, the thickness of the insulating layer 30 is between 0.5 μm and 5 μm.

On a side of the insulating layer 30 facing away from the carrier substrate 10 a buried layer 40 may be arranged. However, the buried layer 40 is optional. The buried layer 40 is arranged on the insulating layer 30. The buried layer may comprise a semiconductor material, for example Si. The buried layer 40 is highly doped. For example, the buried layer 40 is doped for a first type of electric conductivity. The first type of electric conductivity may be n-type. Thus, the buried layer may form an N+-type buried layer. A second type of electric conductivity may be p-type. However, the types of electric conductivity may also be interchanged, i.e. the first type of electric conductivity may be p-type and the second type of electric conductivity may be n-type. The buried layer 40 completely covers the insulating layer 30. In the transversal direction z the buried layer 40 has a thickness, which may be tuned to the required response of the photodetector device in the blue range of wavelengths. For example, the thickness of the buried layer is smaller than 1 μm. The buried layer 40 may be epitaxially grown. The buried layer 40 may also be formed by implantation.

Further, on a side of the insulating layer 30 facing away from the carrier substrate 10 a device layer 20 is arranged.

This means that the device layer 20 is arranged at the main surface 15 of the carrier substrate 10, such that the insulating layer 30 is arranged between the device layer 20 and the carrier substrate 10. The device layer 20 is arranged on or above the insulating layer 30. The device layer 20 may comprise a semiconductor material, for example Si. Further, the device layer may have a doping, in particular a doping for the first type of electric conductivity, e.g. n-type. If a buried layer 40 is present between the insulating layer 30 and the device layer 20, the device layer 20 may have the same type of electric conductivity as the buried layer 40. However, the doping concentration of the device layer 20 may be smaller than the doping concentration of the buried layer 40. The device layer 20 may form an N-type epi-layer. This means that the device layer 20 may be epitaxially grown. In the transversal direction z the device layer 20 may have a thickness of at least 5 μm and at most 10 μm. The device layer 20 may have a specific electrical resistivity of about 100002 cm. The described arrangement of the carrier substrate 10, the insulating layer 30 and the device layer 20 may form a silicon-on-insulator wafer (SOI-wafer).

In FIG. 2 an intermediate product of the fabrication method after further processing steps is shown. In the intermediate product according to FIG. 2 a plurality of photodetector elements 50 are formed in the device layer 20. Forming the photodetector elements 50 comprises forming pn-junctions in the device layer 20, such that each photodetector element 50 is formed by at least one photodiode. For example and as shown in FIG. 2, the photodetector elements 50 may be formed by so-called PIN photodiodes, where an intrinsically doped region 51 (I-region) is arranged between a P+-type doped anode region 52 and an N+-type doped cathode region 53.

The P+-type doped anode region 52 and N+-type doped cathode region are thus not in direct contact, and when a reverse voltage is applied, a larger space charge region is formed than in the classical pn-diode. In particular, each photodetector element 50 may comprise exactly one photodiode. However, it is also possible that each photodetector element 50 comprises more than one photodiode, for example an array of photodiodes.

For example, the N+-type doped cathode region 53 may be formed by the buried layer 40, as shown in FIG. 2. Alternatively, the N+-type doped cathode region 53 is formed by a dedicated implanted region. Forming the pn-junctions in the device layer 20 may be conducted by ion implantation. For example, the P+-type doped anode region 52 is formed by counterdoping a surface region of the N-type doped device layer 20. This can mean that the P+-type doped anode region 52 is arranged at the surface of the device layer 20 that faces away from the insulating layer 30. Further, forming the intrinsically doped region 51 may be formed by counterdoping the device layer 20 with an appropriate dose.

Moreover, as shown in FIG. 2, each photodetector element may comprise a guard ring 54. The guard ring 54 may be arranged at the surface of the device layer 20 that faces away from the insulating layer 30. In lateral directions x, y the guard ring 54 may surround a photoactive area of the photodetector elements 50. This can mean that the guard ring 54 is arranged at the periphery of each photodetector element 50. The guard ring may comprise P+-type and N+-type doped zones. The function of the guard ring 54 is to reduce leakage current and to make the PIN photodiode to work at higher potential by increasing the surface avalanche breakdown voltage.

In the embodiment according to FIG. 2 the photodetector elements 50 are separated from each other by trenches 25. However, the trenches 25 are optional. The trenches 25 may be formed by etching and depositing a filling material. The trenches 25 penetrate the device layer 20 and reach the insulating layer 30. The trenches 25 each surround one of the detector elements 50. The trenches 25 are filled with a filling material, for example a dielectric material. For example, the trenches 25 comprise SiO₂.

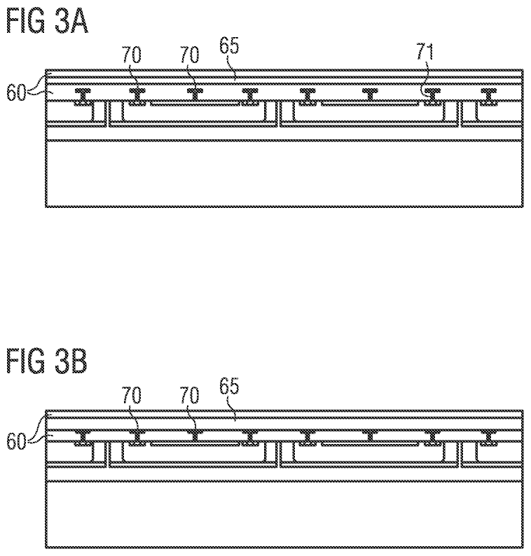

In FIG. 3a an intermediate product of the fabrication method after further processing steps is shown. In the intermediate product according to FIG. 3a an intermetal dielectric 60 is arranged on the device layer 20. The intermetal dielectric 60 comprises an electrically isolating material, for example SiO₂. The intermetal dielectric 60 may be deposited on the device layer 20 by one or more deposition steps.

Further, contact pads 70 are embedded in the intermetal dielectric 60. The contact pads 70 are electrically connected to the photodetector elements 50. The contact pads 70 may be electrically connected by means of via plugs to the photodetector elements 50. In particular, the contact pads 70 may be electrically connected to the cathode region and the anode region of each of the photodetector elements 50. Further, they may be electrically connected to the guard ring 54. The contact pads 70 and the via plugs 71 may comprise a metal. For example, the contact pads 70 and the via plugs 71 comprise aluminum (Al), aluminum doped with copper (AlCu) and/or tungsten. The contact pads may form part of a wiring layer typically used in a CMOS process. However, in the described fabrication method only one or two wiring layers may be used. This can means that in the intermetal dielectric 60 at most one wiring layer or at most two wiring layers are arranged, the contact pads 70 being formed by the at most one wiring layer or by one of the at most two wiring layers, respectively. Thus, the electrical connection from the contact pads 70 to the respective photodetector element 50 are short to keep series resistances and inductances low.

As shown in FIG. 3a, forming the intermetal dielectric 60 on the device layer 20 may further comprise forming a passivation layer 65. The passivation layer 65 may comprise silicon nitride (Si₃N₄), by way of example. The passivation layer 65 forms a portion of the intermetal dielectric 60. The passivation layer 65 may be embedded in the remaining intermetal dielectric, i.e. it may be embedded in SiO₂ and cover the entire device layer 20. In the transversal direction z the passivation layer 65 may be arranged above the contact pads 70. This can mean that the passivation layer 65 is not in direct contact with the contact pads 70, but at a distance to the contact pads.

However, it is also possible that the passivation layer 65 is arranged on the contact pads 70, such that it is in direct contact with them. This embodiment is shown in FIG. 3b and has the advantage that the passivation layer 65 effectively serves as an etch stop layer to improve a later hydrogen fluoride (HF) etch described below.

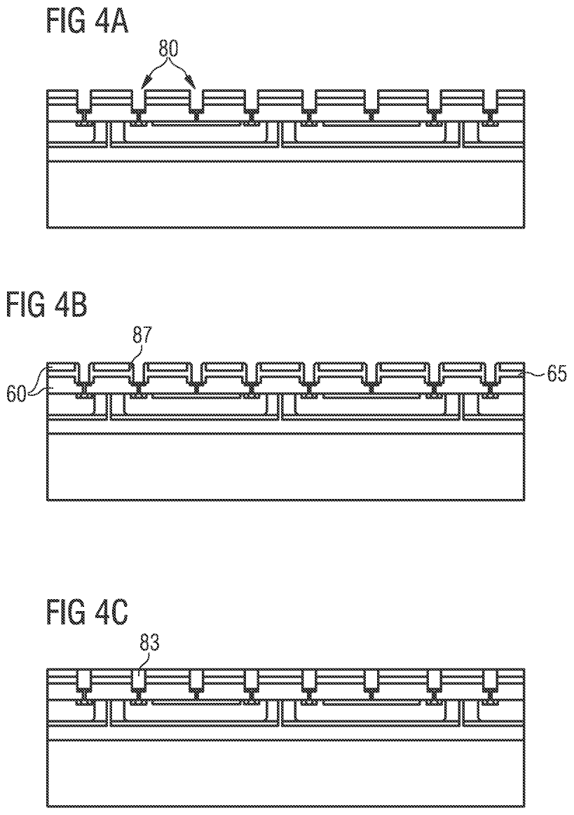

In FIG. 4a an intermediate product of the fabrication method after further processing steps is shown. In the intermediate product according to FIG. 4a pad openings 80 are formed in the intermetal dielectric 60. The pad openings are formed by etching. The pad openings 80 penetrate a portion of the intermetal dielectric 60 including the passivation layer 65. The pad openings 80 reach the contact pads 70. Thus, the contact pads 70 are accessible via the pads openings 80. The contact pads 70 are accessible from a side of the intermetal dielectric 60 facing away from the device layer 20.

FIG. 4b shows an intermediate product after an optional subsequent processing step. In the embodiment according to FIG. 4b a spacer material is deposited into the pad openings 80. Further, the spacer material is removed from the contact pads 70, such that the contact pads are exposed again. However, the spacer material remains on sidewalls of the pad openings 80, such that spacers 87 are formed. The spacers 87 cover the sidewalls of the pad openings 80. The spacer material may comprise the same material as the passivation layer 65, in particular Si₃N₄. Thus, the spacers 87 may serve as etch stop layer to improve a later hydrogen fluoride (HF) etch described below.

Additionally or alternatively, each pad opening 80 can be filled with an electrically conductive plug 83, as shown in FIG. 4c. The electrically conductive plug 83 may serve as etch stop layer to improve a later hydrogen fluoride (HF) etch described below. Additionally, the electrically conductive plug 83 is already useable for a later thermo-compression bonding as described below. For example, the electrically conductive plug 83 comprises aluminum germanium (AlGe), indium tin oxide (ITO), tungsten (W) or titanium nitride (TiN). The electrically conductive plug 83 completely fills the pad opening 80.

In the subsequent FIGS. 5-12 further processing of the alternative embodiment according to FIG. 4a is shown. However, a person skilled in the art will easily be able to apply the presented manufacturing method also to the embodiments according to FIGS. 4b and 4c.

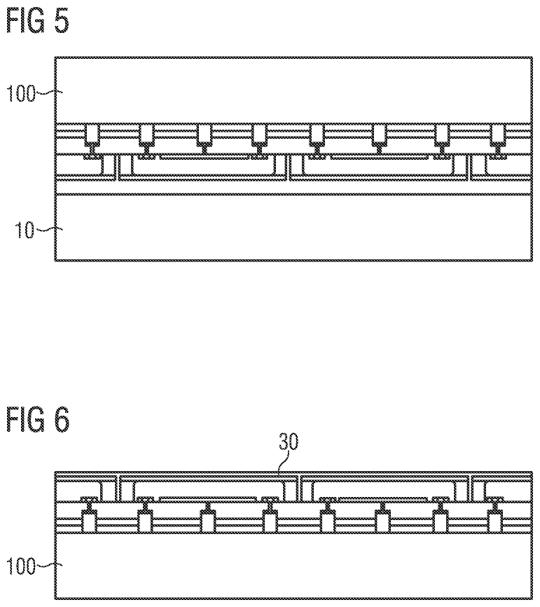

As shown in FIG. 5, a handling substrate 100 is mounted on the intermetal dielectric 60. The handling substrate could be a semiconductor wafer or the like. Mounting the handling substrate 100 on the intermetal dielectric 60 may in particular comprise a bonding technique as fusion bonding or bonding by means of an adhesive. However, it is also possible that the handling substrate 100 is mounted by means of an electrostatic force or by a surface roughening method. In the former case, the handling substrate 100 can also be an electrostatic chuck. A shown in FIG. 5, the pad openings 80 are covered by the handling substrate 100. It has been found that bonding the handling substrate onto the intermetal dielectric 60 with open pad openings 80 is possible as long as the relation between pad area to entire bonding area is small. After mounting the handling substrate 100 the layer stack is turned upside down for backside treatment, as shown in FIG. 6.

In a next step the carrier substrate 10 is removed (FIG. 6). The removal can be conducted by chemical mechanical polishing (CMP), for instance. In a preferred embodiment, the removal is finalized by an etching step using the insulating layer 30 as etch stop layer. By this procedure, the insulating layer 30 may be thinned as well. For example, the remaining insulating layer may have a thickness smaller than 1 μm.

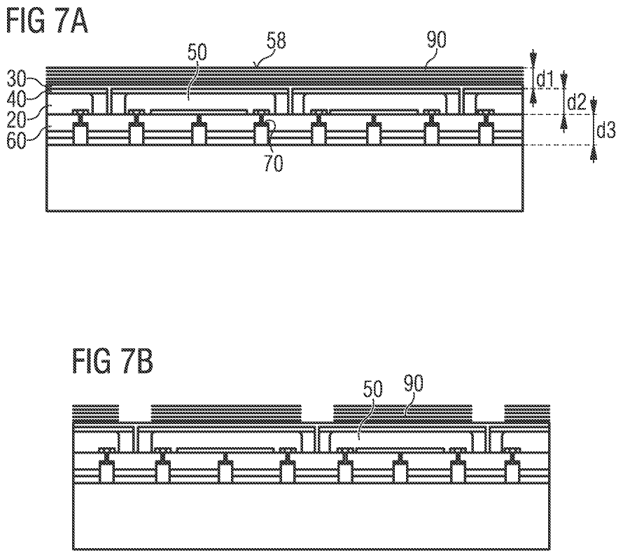

FIG. 7a shows an intermediate product after an optional further processing step. In the embodiment according to FIG. 7a an interference filter 90 is applied on the exposed insulating layer 30. The interference filter 90 may comprise a layer stack, for example layers of silver (Ag), hafnium (Hf), niobium (Nb) and/or dielectric layers. The side of the interference filter 90 facing away from the insulating layer forms a radiation entrance side 58 of the later photodetector chip 55.

Further, FIG. 7a shows the thicknesses d1-d3 of the interference filter 90 including the remaining portion of the insulating layer 30, the device layer 20 including the possible buried layer 40, and the intermetal dielectric 60, respectively. The thickness d1 of the interference filter 90 including the remaining portion of the insulating layer 30 may be at least 1 μm and at most 3 μm. The thickness d2 of the device layer 20 including the possible buried layer 40 may be at least 5 μm and at most 10 μm. The thickness d3 of the intermetal dielectric may be between 0.5 μm and 2 μm.

The thicknesses d1 and d2 together determine the distance of a space charge region of the photodetector element 50 to the radiation entrance side 58. The space charge region of the photodetector element 50 has a distance to the radiation entrance side 58, such that incident electromagnetic radiation in the visible range generates photo-induced charge carriers in the space charge region. The thickness d3 of the intermetal dielectric 60 determines a length of the electrical connections from the contact pads 70 to the respective photodetector element 50. The electrical connections can be short to keep series resistances and inductances low.

In FIG. 7b a further optional process step is illustrated. The further optional process step comprises structuring of the interference filter 90. In the intermediate product according to FIG. 7b the interference filter is structured, such that dedicated portions of the layer stack cover respective photodetector elements 50. As shown in FIG. 7b, the interference filter 90 is removed from regions where no photodetector element 50 is underneath. Structuring the interference filter 90 can be conducted by any lithographic means, for example be a lift-off process or by a standard lithographic process including plasma etching.

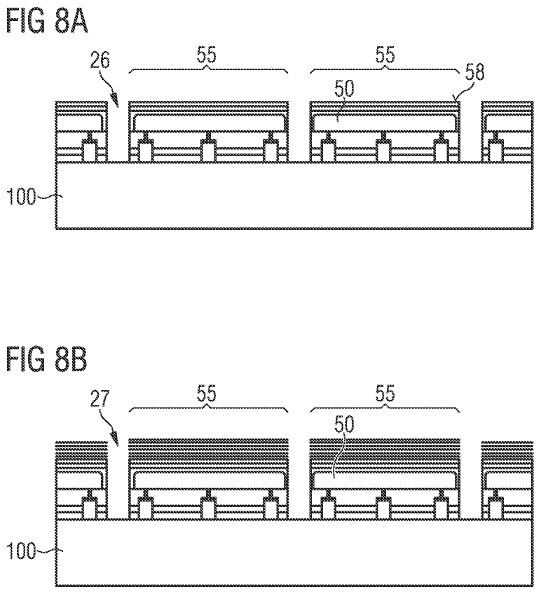

However, it is also an option to not structure the interference filter 90 at this stage, but during singulating the photodetector elements 50 into separate photodetector chips 55, as described below in conjunction with FIG. 8b.

Referring to FIG. 8a, the plurality of photodetector elements 50 are singulated in a next process step.

By singulating the photodetector elements 50 a plurality of separate photodetector chips 55 comprising one photodetector element 50 are formed. In the embodiment according to FIG. 8a no interference filter 90 is arranged on top of the photodetector elements 50. Thus, the radiation entrance side 58 is formed by the insulating layer 30. In this case singulating can preferably be conducted by an etching process in a frontend fabrication plant, as no contaminating materials are present. The etching process comprises etching a lane 26 from the insulating layer 30 up to the handling substrate 100, such that the lane 26 penetrates the insulating layer 30, the device layer 20 and the intermetal dielectric 60. Etching the lane 26 can preferably conducted along the lines of the trench 25. Thus, the trench 25 provides a clear definition of the line where the photodetector elements 50 need to get singulated.

In the alternative embodiment according to FIG. 8b, where an interference filter 90 is arranged on top of the photodetector elements 50, the singulating process is preferably not conducted in a frontend fabrication plant since the interference filter comprises materials that can cause contamination. However, the singulating process can be conducted, for example, in a backend fabrication plant by means of an ablation dicing process. During the ablation dicing process, dicing lanes 27 are formed along the lines of the trenches 25. For example, a protective layer can be used during laser ablation, such that adhesion of debris is reduced and the device reliability is improved. For example, the protective layer is a resin such as HogoMax from DISCO. As outlined above, the interference filter 90 can optionally be structured by the dicing process, such that no lithographic steps are necessary.

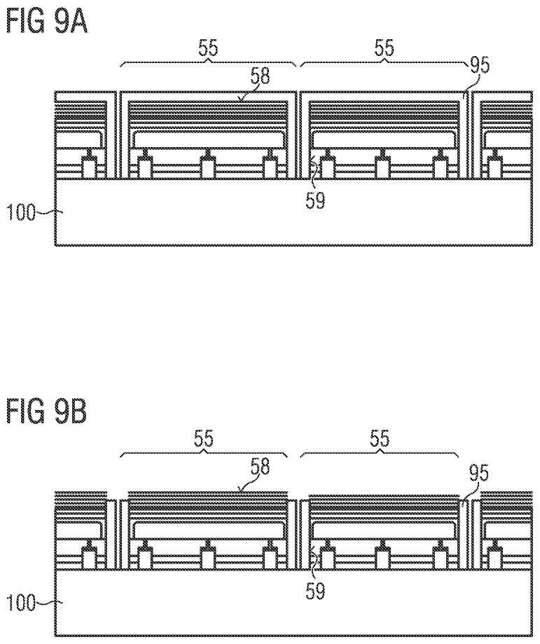

The subsequent FIGS. 9 to 12 show the photodetector chips 55 with the interference filter 90. However, it is noted again that the interference filter 90 is only optional and can be omitted.

In FIGS. 9a and 9b further optional process steps are illustrated. The further optional process steps comprise the application of a polymer encapsulation 95. Applying the polymer encapsulation 95 is optional and may depend on defect requirements of a later transfer process. Moreover, the polymer encapsulation 95 may provide an aperture of each photodetector chip 55, such that stray light cannot enter the photodetector chip 55 from a side surface 59 of the photodetector chip 55. The side surface 59 is perpendicular to the radiation entrance side 59 of the photodetector chip 55.

In the embodiment of FIG. 9a a polymer encapsulation is applied onto each photodetector chip 55. After the deposition step, the polymer encapsulation covers the radiation entrance side 58 as well as the side surface 59 of each photodetector chip 55. After that, the polymer encapsulation 95 is etched back from the radiation entrance side 58, such that the polymer encapsulation 95 only covers the side surfaces 59 of each photodetector chip 55 (see FIG. 9b). The polymer encapsulation 95 may cover the entire side surface 59 of the photodetector chip 55, such that the polymer encapsulation 95 is in direct contact with the handling wafer 100.

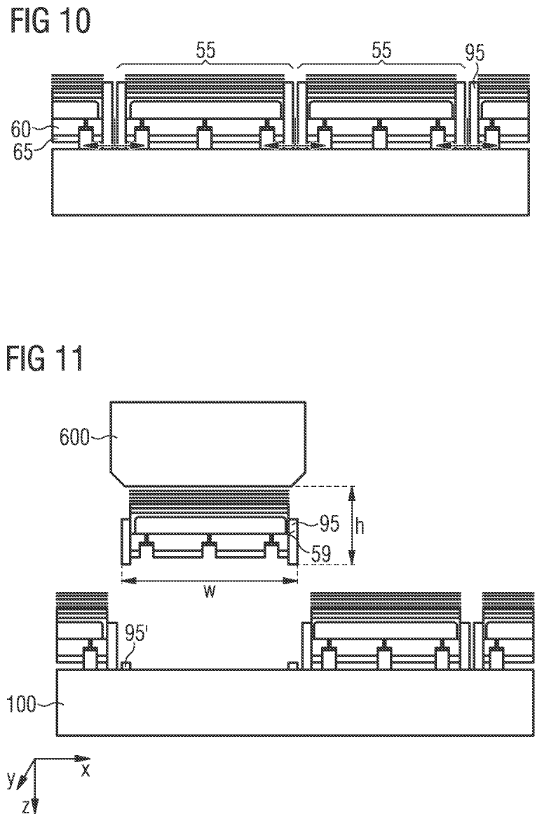

FIG. 10 shows a preferred process for releasing the photodetector chips 55 from the handling substrate 100. As illustrated in FIG. 10, releasing the photodetector chips 55 from the handling substrate 100 may comprise an underetch, wherein parts of the intermetal dielectric 60 are removed, and wherein an etch stop layer 65, 83, 87 is configured to prevent further etching of the intermetal dielectric 60. In the shown example, the passivation layer 65 serves as the etch stop layer 65.

The underetch comprises applying an etchant, for example applying HF vapor, wherein the etchant reaches the intermetal dielectric 60 at the interface to the handling substrate 100. This is because at the interface between the polymer encapsulation 95 and the handling wafer 100, the polymer encapsulation 95 may have some weak spots or may be porous, such that the etchant can penetrate through the polymer encapsulation 95, as illustrates by arrows in FIG. 10. In turn, the intermetal dielectric 60 is etched by the etchant releasing the photodetector chips 55 from the handling substrate 100. In the example of FIG. 10 the photodetector chips 55 are still weakly fixed to the handling substrate 100 by means of the polymer encapsulation 95.

The passivation layer is configured to be resistant to the etchant. Thus, the passivation layer protects against further etching. The passivation layer 65 is provided to ensure that the etchant, e.g. the HF vapor, only etches the intermetal dielectric 60 near the interface to the handling substrate 100. However, there are some further optional embodiments to improve the stability of the process of underetching the structure with vapor HF, as outlined above.

For example, as shown in FIG. 3b, the passivation layer 65 may be in direct contact with the contact pads 70 that are embedded in the intermetal dielectric 60. This ensures that the surroundings of the contact pads 70 are not attacked by the HF vapor. This in turn improves the reliability of the device.

Instead, spacers 87 can be applied to the pads openings 80, as shown in FIG. 4b. The spacers 87 may comprise the same material as the passivation layer 65, thus being configured to be resistant to the etchant. This also ensures that the surroundings of the contact pads 70 are not attacked by the HF vapor. Further, as shown in FIG. 4c, each pad opening 80 can be filled with an electrically conductive plug 83. The electrically conductive plug 83 may also serve as etch stop layer to improve the releasing process. Moreover, the pad openings 80 can be filled with another material that is resistant against the etchant but can be removed after the later transfer process.

In other embodiments, where the handling substrate 100 is mounted on the intermetal dielectric 60 by means of an electrostatic force, releasing the handling wafer 100 can be conducted by releasing the electrostatic force. Moreover, in cases where mounting the handling substrate 100 comprises a surface roughening method, releasing can be conducted by applying a shear force. If mounting includes the application of an adhesive, the adhesive can be dissolved during the releasing process.

In the next process step according to FIG. 11 the pick-up of the photodetector chips 55 is carried out by a transfer device 600. In a preferred embodiment, the transfer device 600 is an elastomer stamp 600. In FIG. 11 the width w and the height h of one of the photodetector chips are illustrated. In the transversal direction z each photodetector chip 55 has the height h. For example, the height h is at most 10 μm, 15 μm or 20 μm. In lateral directions x, y each photodetector chip 55 has the width w. For example, the width w is at most 20 μm, 25 μm or 30 μm. However, conventional pick-and place devices may also be used, if the dimensions of the photodetector chips are suited for them.

As shown in FIG. 11, the polymer encapsulation 95 covering the side surface 59 of the photodetector chip 55 may form a predetermined breaking point near the handling substrate 100. Thus, a remainder 95′ of the polymer encapsulation 95 may remain on the handling substrate 100.

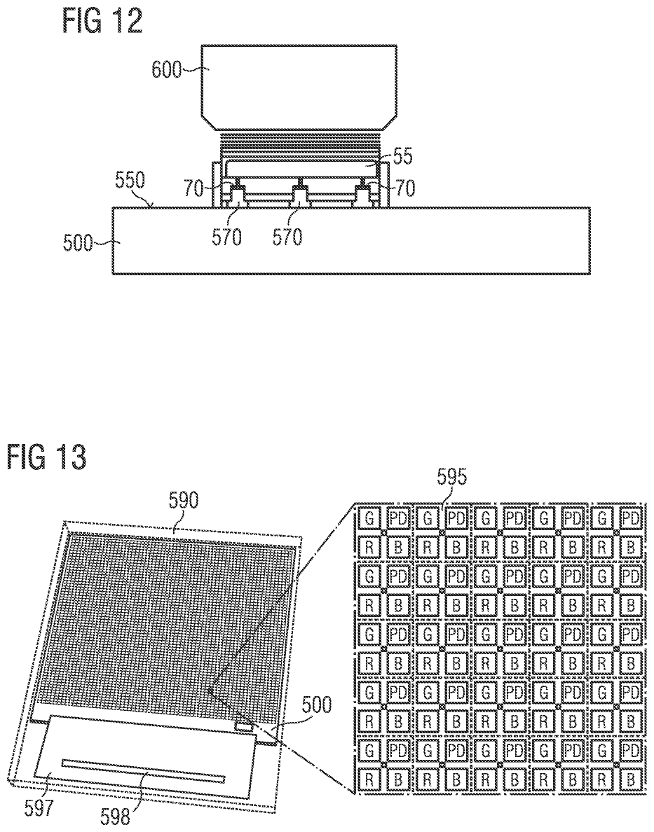

The picked photodetector chip 55 is then transferred onto a target substrate 500 comprising a main surface 550 and electrodes 570 on the main surface 550 (see FIG. 12). For example, the target substrate 500 is a printed circuit board (PCB), or a glass substrate. In a preferred embodiment, the target substrate 500 forms a backplane of a display 590 (see FIG. 13).

The photodetector chip 55 is mounted on the target substrate 500 such that the intermetal dielectric 60 faces the main surface 550 of the target substrate 500, and such that the device layer 20 faces away from the target substrate 500. Thus, the photodetector chip 55 forms a backside illuminated device. The contact pads 70 are electrically connected to the electrodes 570. For example, this can be achieved by thermo-compression bonding. The electrodes can comprise a metallic material, for example gold (Au). For example, the electrodes 570 form micro-bumps that are aligned to the pad openings 80, such that the electrodes 570 reach into the pads openings 80. In embodiments, where the pad openings 80 are filled by an electrically conductive plug 83, the electrically conductive plug 83 can be used for the thermo-compression bonding as well. In addition, an adhesive layer (not shown) may be present between the target substrate 500 and the photodetector chip 55 at regions, where no electrodes are arranged.

After mounting the photodetector chip 55 onto the target substrate 500, the transfer device 600 is removed (not shown). If the transfer device 600 is an elastomer stamp 600, for example, it can be removed by applying a shear force to the elastomer stamp 600.

A multitude of photodetector chips 55 may be mounted onto the target substrate 500 in the described way. In this way a photodetector device is formed which may be used in camera applications, by way of example.

In FIG. 13 a display 590 comprising the photodetector device of FIG. 12 is shown. In this embodiment, the target substrate 500 forms a backplane of the display 590. Moreover, light emitting elements R, G, B are arranged between the photodetector chips 55 (denoted with “PD” in FIG. 13) on the target substrate 500. This can mean that the light emitting elements R, G, B are arranged at the same level as the photodetector chips 55 and are arranged next to them. As shown in the right part of FIG. 13, which is an enlarged view of a portion of the display, the light emitting elements R, G, B and the photodetector chips 55 may form pixels 595, such that one light emitting element R, G, B of each color and one photodetector chip 55 form one pixel 595. In particular, the light emitting elements R, G, B may be μLEDs (μLED: micro light emitting diode). In particular, the display 590 forms a wearable device display, a television display, a computer display, a laptop display, a tablet display, a smartphone display, or an automotive head-up display. The display 590 may further comprise a flex connection 597 with a driver and frontend readout, as well as a display controller 598 as separate die bonded on the flex connection 597, as shown in FIG. 13.

The embodiments of the photodetector device and the method of producing the photodetector device disclosed herein have been discussed for the purpose of familiarizing the reader with novel aspects of the idea. Although preferred embodiments have been shown and described, many changes, modifications, equivalents and substitutions of the disclosed concepts may be made by one having skill in the art without unnecessarily departing from the scope of the claims.

The term “comprising”, insofar it was used in the claims or in the description, does not exclude other elements or steps of a corresponding feature or procedure. In case that the terms “a” or “an” were used in conjunction with features, they do not exclude a plurality of such features. Moreover, any reference signs in the claims should not be construed as limiting the scope.

It will be appreciated that the disclosure is not limited to the disclosed embodiments and to what has been particularly shown and described hereinabove. Rather, features recited in separate dependent claims or in the description may advantageously be combined. Furthermore, the scope of the disclosure includes those variations and modifications, which will be apparent to those skilled in the art and fall within the scope of the appended claims.

1-20. (canceled)

21. A method for fabricating a photodetector device, the method comprising:
providing a carrier substrate, wherein a device layer is arranged at a main surface of the carrier substrate, and an insulating layer is arranged between the device layer and the carrier substrate;
forming a plurality of photodetector elements in the device layer;
forming an intermetal dielectric on the device layer, wherein contact pads electrically connected to the photodetector elements are embedded in the intermetal dielectric;
forming pad openings in the intermetal dielectric, the pad openings reaching the contact pads so that the contact pads are accessible via the pad openings;
mounting a handling substrate on the intermetal dielectric;
removing the carrier substrate;
singulating the plurality of photodetector elements such that a plurality of separate photodetector chips comprising one photodetector element are formed;
releasing the photodetector chips from the handling substrate; and
transferring the photodetector chips on a target substrate comprising a main surface such that the intermetal dielectrics face the main surface of the target substrate.

22. The method according to claim 21, further comprising providing a highly doped buried layer between the insulating layer and the device layer, wherein the highly doped buried layer comprises the same type of electric conductivity as the device layer.

23. The method according to claim 21, further comprising, before forming the intermetal dielectric on the device layer, forming trenches penetrating the device layer, wherein each of the trenches surrounds one of the detector elements and is filled with a filling material.

24. The method according to claim 21, wherein forming the intermetal dielectric on the device layer further comprises forming a passivation layer on or above the contact pads.

25. The method according to claim 21, further comprising, after forming the pad openings, filling the pad openings with an electrically conductive plug and/or covering sidewalls of the pad openings with a spacer.

26. The method according to claim 21, further comprising, after removing the carrier substrate that exposes the insulating layer, forming an interference filter on the insulating layer.

27. The method according to claim 21, further comprising, after singulating the plurality of photodetector elements, applying a polymer encapsulation that covers side surfaces of the photodetector chips.

28. The method according to claim 21, wherein releasing the photodetector chips from the handling substrate comprises performing an under-etch, wherein parts of the intermetal dielectric are removed, and wherein an etch stop layer prevents further etching of the intermetal dielectric.

29. The method according to claim 21, wherein transferring the photodetector chips onto the target substrate comprises a parallel transfer of a plurality of photodetector chips by using an elastomer stamp.

30. The method according to claim 21, further comprising electrically connecting the contact pads to electrodes that are arranged on the main surface of the target substrate.

31. A photodetector device comprising:
a target substrate having a main surface;
a plurality of separate photodetector chips, wherein each photodetector chip comprises a device layer that is arranged at a backside of the photodetector chip, and wherein a photodetector element is arranged in the device layer; and
an intermetal dielectric arranged at a front side of the photodetector chip, wherein contact pads electrically connected to the photodetector element are embedded in the intermetal dielectric and accessible via pad openings in the intermetal dielectric,
wherein each photodetector chip is mounted on the target substrate such that the front side of the photodetector chip faces the main surface of the target substrate.

32. The photodetector device according to claim 31, wherein each photodetector chip further comprises a highly doped buried layer arranged on the device layer at a side facing away from the intermetal dielectric, and wherein the highly doped buried layer comprises the same type of electric conductivity as the device layer.

33. The photodetector device according to claim 31, wherein the photodetector element forms a photodiode comprising at least one pn-junction and a space charge region.

34. The photodetector device according to claim 33, wherein the space charge region of the photodetector element has a distance to a radiation entrance side of the photodetector chip such that incident electromagnetic radiation in a visible range generates photo-induced charge carriers in the space charge region.

35. The photodetector device of claim 34, wherein the target substrate forms a backplane of a display, and wherein light emitting elements are arranged between the photodetector chips on the target substrate.

36. The photodetector device according to claim 31, wherein each photodetector chip further comprises an interference filter arranged on or above the device layer at the backside of the photodetector chip configured to face incident electromagnetic radiation.

37. The photodetector device according to claim 31, wherein each photodetector chip further comprises a polymer encapsulation covering side surfaces of the photodetector chip.

38. The photodetector device according to claim 31, wherein at most one wiring layer or at most two wiring layers are arranged in the intermetal dielectric, wherein the contact pads is formed by the at most one wiring layer or by one of the at most two wiring layers, respectively.

39. The photodetector device according to claim 31,
wherein, in a transversal direction, each photodetector chip has a height, the height being at most 10 μm, 15 μm or 20 μm, and/or
wherein, in lateral directions, each photodetector chip has a width, the width being at most 20 μm, 25 μm or 30 μm.

40. A display comprising:
the photodetector device of claim 31,
wherein the display is a wearable device display, a television display, a computer display, a laptop display, a tablet display, a smartphone display, or an automotive head-up display.
